(19) United States
(12) Patent Application Publication
(10) Pub. No.: US 2012/0026248 A1
(43) Pub. Date: Feb. 2, 2012

(54) Inkjet head assembly and method for manufacturing the same

(75) Inventors: Young Jae Kim, Suwon (KR); Hwa Sun Lee, Hwaseong (KR); Jae Woo Joung, Suwon (KR)

(73) Assignee: SAMSUNG ELECTRO-MECHANICS CO., LTD., Suwon (KR)

(21) Appl. No.: 13/064,388

(22) Filed: Mar. 22, 2011

(30) Foreign Application Priority Data
Jul. 30, 2010 (KR) 10-2010-0074146

(51) Int. Cl. B41J 2/04; H05K 13/00

(52) U.S. Cl. 347/54; 29/592.1

(57) ABSTRACT

There are provided an inkjet head assembly and a method for manufacturing the same. The inkjet head assembly includes: an inkjet head plate having an ink flow passage formed therein and having an actuator formed thereon, the actuator providing driving force for discharging ink; a flexible printed circuit board (FPCB) applying voltage to the actuator; and an intermediate substrate provided so as to electrically connect the actuator to the flexible printed circuit board and having a second bonding portion bonded to the flexible printed circuit board formed inwardly of a first bonding portion, bonded to the actuator in a width direction of the inkjet head plate.

### CROSS-REFERENCE TO RELATED APPLICATIONS

This application claims the priority of Korean Patent Application No. 10-2010-0074146 filed on Jul. 30, 2010, in the Korean Intellectual Property Office, the disclosure of which is incorporated herein by reference.

### BACKGROUND OF THE INVENTION

1. Field of the Invention

The present invention relates to an inkjet head assembly, and more particularly, an inkjet head assembly in which a connection structure of a flexible printed circuit board (FPCB) applying voltage to a piezoelectric actuator for driving an inkjet head is improved to reduce a width of the inkjet head such that the productivity of the inkjet head is improved, and a method for manufacturing the same.

2. Description of the Related Art

Generally, an inkjet head converts an electrical signal into physical power to discharge ink in droplet form through a small nozzle. The inkjet head may be divided into two main types according to an ink discharging method. One type is a thermal inkjet head generating bubbles in ink using a heat source to discharge the ink by the expansive force of the bubbles, and the other type is a piezoelectric inkjet head using a piezoelectric element to discharge ink by pressure applied to the ink due to the deformation of the piezoelectric element.

In order to drive the piezoelectric inkjet head, an electrical signal should be applied to an actuator thereof. Generally, voltage is applied to the actuator by connecting a flexible printed circuit board (FPCB) to the actuator and connecting the FPCB to an inkjet head driving driver.

Generally, since an ink tank for supplying the ink to the inkjet head is disposed at an outer side of the actuator, when the FPCB is connected to the actuator, a space for bending the FPCB from a connection portion between the FPCB and the actuator to an upper portion of the ink tank is required. As a result, a width of the inkjet head is increased, and the number of the inkjet heads capable of being manufactured on a single wafer in the case of an inkjet head manufactured at a wafer level is reduced, which causes a deterioration in productivity such as a decrease in processing yield, an increase in a manufacturing costs, and the like.

In addition, physical stress applied to the FPCB is increased due to warp deformation of the FPCB, and connection defects such as electrical short-circuits at a bonding portion between the FPCB and the actuator due to elasticity of the FPCB, or the like, are generated.

### SUMMARY OF THE INVENTION

An aspect of the present invention provides an inkjet head assembly in a connection structure between an inkjet head and a FPCB is improved to reduce the entire width of the inkjet head and increase the number of inkjet heads capable of being manufactured on a single wafer such that productivity is improved, for example, an increase in processing yield, a decrease in manufacturing costs, and the like, and a method for manufacturing the same.

Another aspect of the present invention also provides an inkjet head assembly, capable of reducing physical stress applied to a FPCB and improving bonding characteristics of the FPCB when the FPCB is connected to an inkjet head, and a method for manufacturing the same.

According to an aspect of the present invention, there is provided an inkjet head assembly, including: an inkjet head plate having an ink flow passage formed therein and having an actuator formed thereon, the actuator providing driving force for discharging ink; a flexible printed circuit board (FPCB) applying voltage to the actuator; and an intermediate substrate provided so as to electrically connect the actuator to the flexible printed circuit board and having a second bonding portion bonded to the flexible printed circuit board formed inwardly of a first bonding portion, bonded to the actuator, in a width direction of the inkjet head plate.

A conductor pattern connecting the first bonding portion to the second bonding portion may be formed in the intermediate substrate.

Each of a first terminal electrode and a second terminal electrode may be formed at positions corresponding to the first and second bonding portions of the conductor pattern.

The intermediate substrate may include: a wiring pattern formed on one surface of the intermediate substrate; and a via conductor formed to penetrate through the intermediate substrate from one of the first bonding portion and the second bonding portion and connected to the wiring pattern.

A cavity may be formed on a lower portion of the intermediate substrate so as to secure a vibration space of the actuator.

The first and second bonding portions may be made of an anisotropic conductive film (ACF).

The intermediate substrate may be a FR-4 (glass epoxy) substrate.

According to another aspect of the present invention, there is provided a method for manufacturing an inkjet head assembly, including: preparing an inkjet head plate having an ink flow passage formed therein and having an actuator formed thereon, the actuator providing driving force for discharging ink; preparing a flexible printed circuit board (FPCB) applying voltage to the actuator; forming a conductor pattern in an intermediate substrate so as to electrically connect the actuator to the flexible printed circuit board; forming a first bonding portion on an upper portion of the actuator and bonding the first bonding portion to a lower portion of the intermediate substrate; forming a second bonding portion at an inner side in a width direction of the inkjet head plate than a first bonding portion on an upper portion of the intermediate substrate; and bonding the flexible printed circuit board to the second bonding portion.

The forming of the conductor pattern in the intermediate substrate may include: forming a via to penetrate through the intermediate substrate at a position corresponding to one of the first bonding portion and the second bonding portion; forming a via conductor by filling the via with a conductive material; and forming a wiring pattern on one surface of the intermediate substrate, the wiring pattern connecting one end of the via conductor to the other of the first bonding portion and the second bonding portion.

The method for manufacturing an inkjet head assembly may further include forming a cavity on a lower portion of the intermediate substrate so as to secure a vibration space of the actuator.

The forming of the cavity may be performed by an etching method.

The first and second bonding portions may be made of an anisotropic conductive film (ACF).

The intermediate substrate may be a FR-4 (glass epoxy) substrate.

The forming of the conductor pattern in the intermediate substrate may include forming each of a first terminal electrode and a second terminal electrode at positions corresponding to the first and second bonding portions of the conductor pattern.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an exploded perspective view schematically showing an inkjet head assembly according to an exemplary embodiment of the present invention;

FIG. 2 is an cut-away perspective view schematically showing the inkjet head assembly according to an exemplary embodiment of the present invention;

FIG. 3 is a cross-sectional view schematically showing the inkjet head assembly according to an exemplary embodiment of the present invention;

FIG. 4 is an enlarged cross-sectional view of an intermediate substrate in the inkjet head assembly according to an exemplary embodiment of the present invention;

FIGS. 5A and 5B are process views showing a method for manufacturing an inkjet head plate of the inkjet head assembly according to an exemplary embodiment of the present invention;

FIGS. 6A to 6C are process views showing a method for manufacturing an intermediate substrate of the inkjet head assembly according to an exemplary embodiment of the present invention; and

FIGS. 7A to 7D are process views showing a method for assembling the inkjet head assembly according to an exemplary embodiment of the present invention.

### DETAILED DESCRIPTION OF THE PREFERRED EMBODIMENT

Exemplary embodiments of the present invention will now be described in detail with reference to the accompanying drawings. However, it should be noted that the spirit of the present invention is not limited to the exemplary embodiments set forth herein and those skilled in the art and understanding the present invention could easily accomplish retrogressive inventions or other exemplary embodiments included in the spirit of the present invention by the addition, modification, and removal of components within the same spirit, but those are to be construed as being included in the spirit of the present invention.

In addition, components having like functions are denoted by like reference numerals throughout the drawings of each exemplary embodiment.

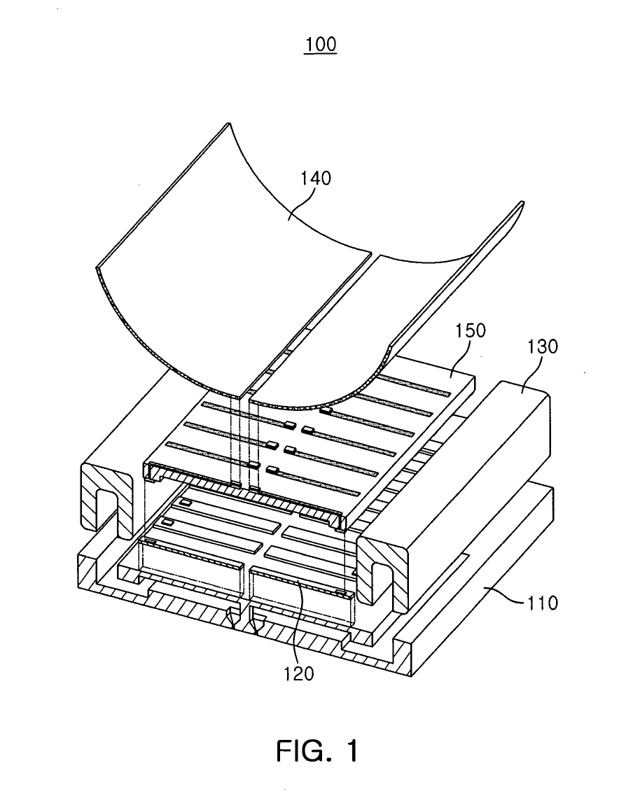

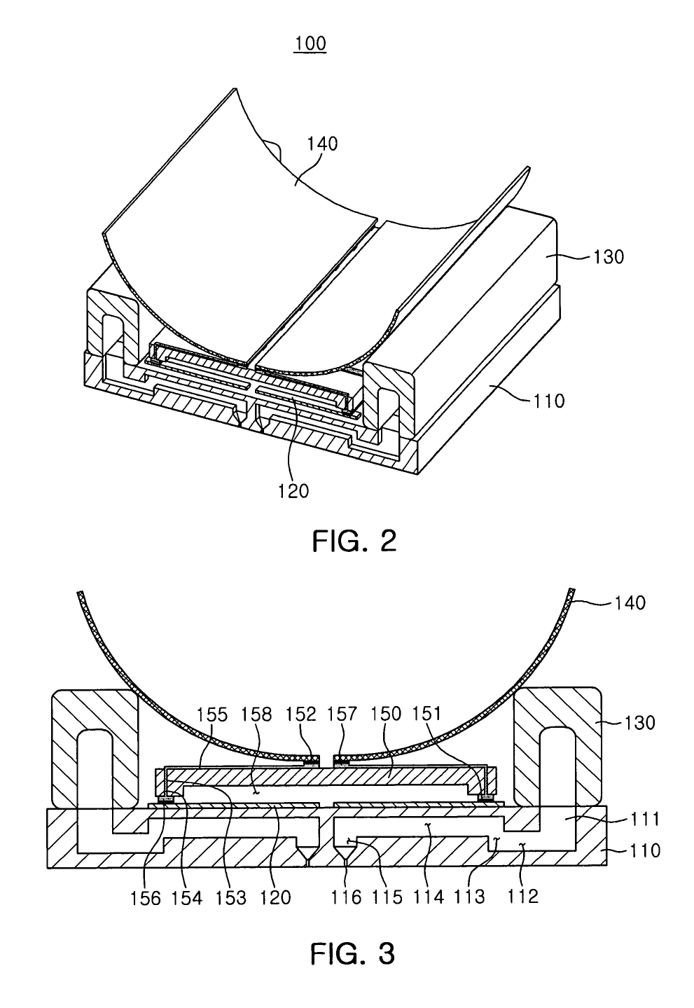

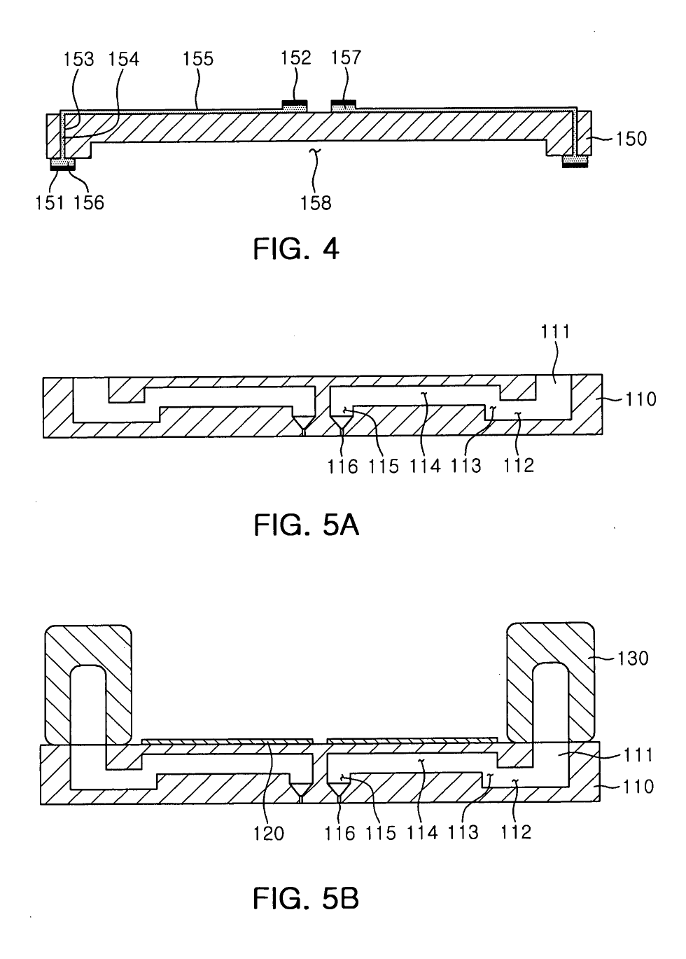

FIGS. 1 through 3 are respectively, an exploded perspective view, a cut-away perspective view, and a cross-sectional view schematically showing an inkjet head assembly according to an exemplary embodiment of the present invention. FIG. 4 is an enlarged cross-sectional view of an intermediate substrate in the inkjet head assembly according to an exemplary embodiment of the present invention.

Referring to FIGS. 1 to 3, an inkjet head assembly 100 according to an exemplary embodiment of the present invention may include an inkjet head plate 110 having an ink flow passage formed therein, a piezoelectric actuator 120 providing driving force for discharging ink to the inkjet head assembly 110, an ink tank 130 supplying the ink to the ink flow passage of the inkjet head plate 110, a flexible printed circuit board 140 applying voltage to the piezoelectric actuator 120, and an intermediate substrate 150 electrically connecting the piezoelectric actuator 120 and the flexible printed circuit board 140.

In the inkjet head assembly 100, an inkjet head is configured to have a plurality of head cells including nozzles, in an amount such as ninety six nozzles, two hundred and fifty six nozzles, or the like, according to the performance of the inkjet head. In the exemplary embodiment, the inkjet head assembly 100 has a structure in which two sets of inkjet heads are arranged in a width direction of the inkjet head plate 110.

Herein, directions of the inkjet head plate 110 are defined as follows. A length direction thereof indicates a direction from one head cell toward another head cell, among the plurality of head cells, and the width direction indicates a direction perpendicular to the length direction in a plane of the inkjet head plate 110.

The inkjet head plate 110 may include ink inlet 111 into which ink is introduced, manifolds 112 transporting the ink introduced into the ink inlets 111 to the ink flow passages of individual head cells, a plurality of pressure chambers 114 provided on a lower portion of a position in which the piezoelectric actuator 120 is mounted, and a plurality of nozzles 116 discharging the ink. A plurality of restrictors 113 may be formed between the manifold 112 and the pressure chambers 114 in order to restrain the ink in the pressure chamber 114 from flowing backward to the manifold 112 when the ink is discharged. In addition, the pressure chambers 114 and the nozzles 116 may be interconnected by a plurality of dampers 115.

The inkjet head plate 110 may be formed by appropriately forming the above-mentioned components configuring the ink flow passage on upper and lower substrates, and bonding the upper and lower substrates each other using a method such as silicon direct bonding (SDB) method or the like. At this time, the upper substrate may be a single crystal silicon substrate or a SOI substrate, and the lower substrate may be a SOI substrate. In addition, the inkjet head plate 110 is not limited thereto but may configure the ink flow passage using more substrates. In some cases, the ink flow passage may be implemented on a single substrate. The components configuring the ink flow passage are also only examples, and an ink flow passage having various configurations may be provided according to requirements and design specifications.

The piezoelectric actuators 120 are formed on an upper portion of the inkjet head plate 110 so as to correspond to the pressure chambers 114 of the inkjet head plate 110, and provide the driving force for discharging the ink introduced into the pressure chambers 114 to the nozzles 116. For example, the piezoelectric actuator 120 may be configured to include a lower electrode serving as a common electrode, a piezoelectric film deformed according to the application of voltage, and an upper electrode serving as a driving electrode.

The lower electrode may be formed on the entire surface of the inkjet head plate 110 and may be made of one conductive metal material; however, it may be preferably formed of two metal thin film layers made of titanium (Ti) and platinum (Pt). The lower electrode serves as a diffusion prevention layer preventing interdiffusion between the piezoelectric film and the inkjet head plate 110 as well as serving as the common electrode. The piezoelectric film is formed on the lower electrode, and is disposed on the upper portion of each of the plurality of pressure chamber 114. The piezoelectric film may be made of a piezoelectric material, preferably, a lead zirconate titanate (PZT) ceramic material. The upper electrode is formed on the piezoelectric film, and may be made of any one material selected from a group consisting of Pt, Au, Ag, Ni, Ti, Cu, and the like.

In the exemplary embodiment of the present invention, a configuration in which the ink is discharged by the piezoelectric driving method using the piezoelectric actuator 120 is exemplary described; however the present invention is not limited by an ink discharging method and may be configured so as to discharge the ink by various methods such as a thermally driven method, or the like.

The ink tank 130 is connected to the ink inlet 111 so as to supply the ink to the ink flow passage of the inkjet head plate 110, and is disposed at an outer side of the piezoelectric actuator 120 in the width direction of the inkjet head plate 110.

The intermediate substrate 150 for electrically interconnecting the piezoelectric actuator 120 and the flexible printed circuit board 140 is formed with a conductor pattern having a predetermined form.

Referring to FIG. 4, first bonding portions 151 for bonding the intermediate substrate 150 to the piezoelectric actuator 120 are formed on a lower surface of the intermediate substrate 150, and second bonding portions 152 for bonding the intermediate substrate 150 to the flexible printed circuit board 140 are formed on an upper surface thereof. The second bonding portion 152 may be formed inwardly of the first bonding portion 152 in the width direction of the inkjet head plate 110.

The intermediate substrate 150 may be configured as a printed circuit board having conductor patterns formed on one surface thereof, and be made of an epoxy resin based substrate, for example, a FR-4 (glass epoxy) substrate.

The conductor patterns formed in the intermediate substrate 150 may include a via conductor 154 filling a via 153 penetrating through the intermediate substrate 150 from the first bonding portion 151 and a wiring pattern 155 formed from the second bonding portion 152 on an upper surface of the intermediate substrate 150 to an upper end of the via conductor 154. That is, a lower end of the via conductor 155 may be connected to the first bonding portion 151, and the upper end thereof may be connected to the wiring pattern 155.

The via 153 may be formed in the intermediate substrate 150 by applying a drilling process using mechanical drilling or laser drilling to the printed circuit board, and the via conductor 154 may be formed by plating a metal in the via 153 through an electroplating method. As the metal, any one selected from a group consisting of Pt, Au, Ag, Ni, Ti, Cu, and the like may be used.

At this time, the conductor patterns formed in the intermediate substrate 150 may include terminal electrodes in order to ensure electrical connections on portions connected to the first and second bonding portions 151 and 152. That is, a first terminal electrode 156 may be formed on the lower end of the via conductor 154 connected to the first bonding portion 151, and a second terminal electrode 157 may be formed on the portion of the wiring pattern 155 connected to the second bonding portion 152.

The first and second bonding portions 151 and 152 may be made of a conductive medium having a bonding force of a level that is not electrically short circuited, for example, a protrusion-shaped connection member such as a solder ball, a solder bump, or the like, and an anisotropic conductive film (ACF). In addition to the above-mentioned medium, the first and second bonding portions 151 and 152 may also be made of various load applying conductive media. In the exemplary embodiment, a case in which the first and second bonding portions 151 and 152 are made of the ACF is assumed.

When the second bonding portion 152 is bonded to the intermediate substrate 150, a polymer film (not shown) may be applied to an upper portion of the wiring pattern 155 in order to protect the wiring pattern 155 formed on the upper surface of the intermediate substrate 150.

A cavity 158 may be formed on a lower portion of the intermediate substrate 150 so as to secure a vibration space of the piezoelectric actuator 120. That is, the cavity 158 is configured such that when the piezoelectric actuator 120 is vibrated, the vibration is not disturbed by the intermediate substrate 150.

The cavity 158 may be formed through an etching process. More specifically, a dry etching method such as a reactive ion etching (RIE) method using inductively coupled plasma (ICP) or a wet etching method using, for example, tetramethyl ammonium hydroxide (TMAH) or potassium hydroxide (KOH) as etchant for silicon may be used.

Although the exemplary embodiment of the present invention has described a case in which the cavity 158 is formed on the lower portion of the intermediate substrate 150, the present invention is not limited thereto and the cavity 158 may not be formed. This is because, in the vibration of the piezoelectric actuator 120, ½ of the amplitude thereof does not exceed the sum of thicknesses of the first bonding portion 151 and the first terminal electrode 156.

The FPCB 140 is coupled to the second bonding portions 152 to be bonded to the intermediate substrate 150. At this time, since the second bonding portions 152 are disposed at the inner side, that is, in the vicinity of the center, in the width direction of the inkjet head plate 110 than the first bonding portions 151, a warp deformation space from the second bonding portions 152 to the outer side of the piezoelectric actuator 120 may be secured.

Therefore, it is unnecessary to separately prepare a space for bending the FPCB 140 between the piezoelectric actuator 120 and the ink tank 130, and the entire width of the inkjet head assembly may be reduced by about 25%.

In addition, since the intermediate substrate 150 is interposed between the FPCB 140 and the piezoelectric actuator 120, a height at which the FPCB 140 is bent to an upper portion of the ink tank 130 is reduced by a thickness of the intermediate substrate 150.

Accordingly, when the FPCB 140 is warped, deformed, it is bent to have a smooth curve, such that physical stress applied to the FPCB 140 is significantly reduced and the FPCB 140 is securely bonded to the intermediate substrate. Therefore, the occurrence of electrical short-circuits in the second bonding portion 152 may be prevented due to the characteristics of the FPCB 140 having elasticity.

Hereinafter, a method for manufacturing an inkjet head assembly according to an exemplary embodiment of the present invention having the above-mentioned configuration will be described.

First, schematically describing a method for manufacturing an inkjet head assembly according to an exemplary embodiment of the present invention, the ink flow passage is formed on a wafer to manufacture the inkjet head plate, the conductor patterns are formed in the substrate to manufacture the intermediate substrate, the intermediate substrate is stacked on and bonded to the inkjet head plate, and the flexible printed circuit board (FPCB) is bonded to the intermediate substrate, such that the inkjet head assembly according to an exemplary embodiment of the present invention is completed. Meanwhile, processes manufacturing the intermediate substrate and the inkjet head plate may be performed regardless of order. That is, any one of the intermediate substrate and the inkjet head plate may be first manufactured, and the intermediate substrate and the inkjet head plate may also be simultaneously manufactured. However, for convenience of explanation, the process of manufacturing the inkjet head plate will be first described below. In addition, the processes of manufacturing the inkjet head plate are generally the processes forming the ink flow passage in at least one wafer. Hereinafter, for convenience of explanation, a detailed description of the processes of manufacturing the inkjet head plate will be omitted.

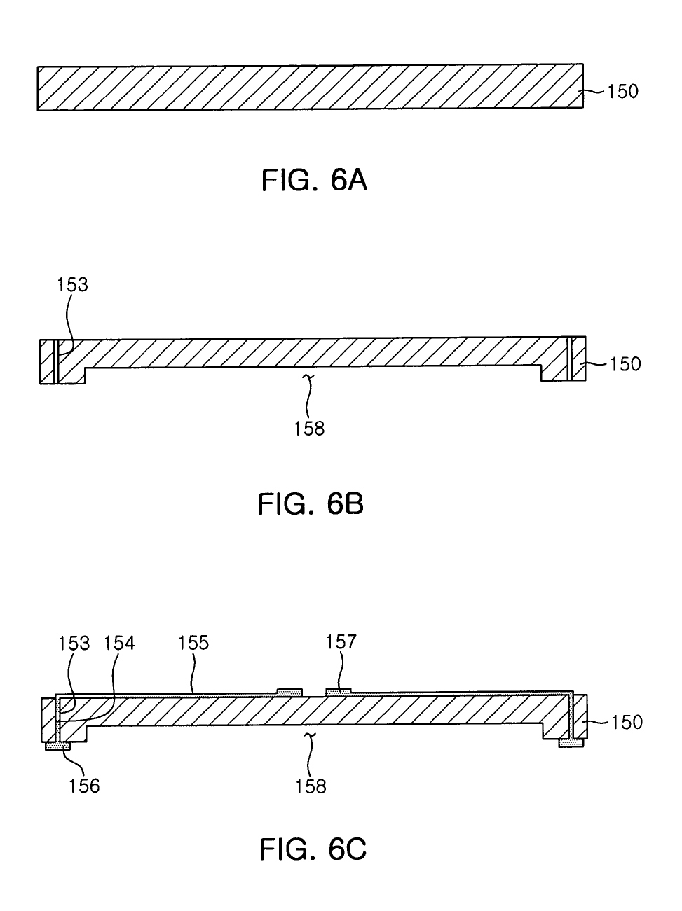

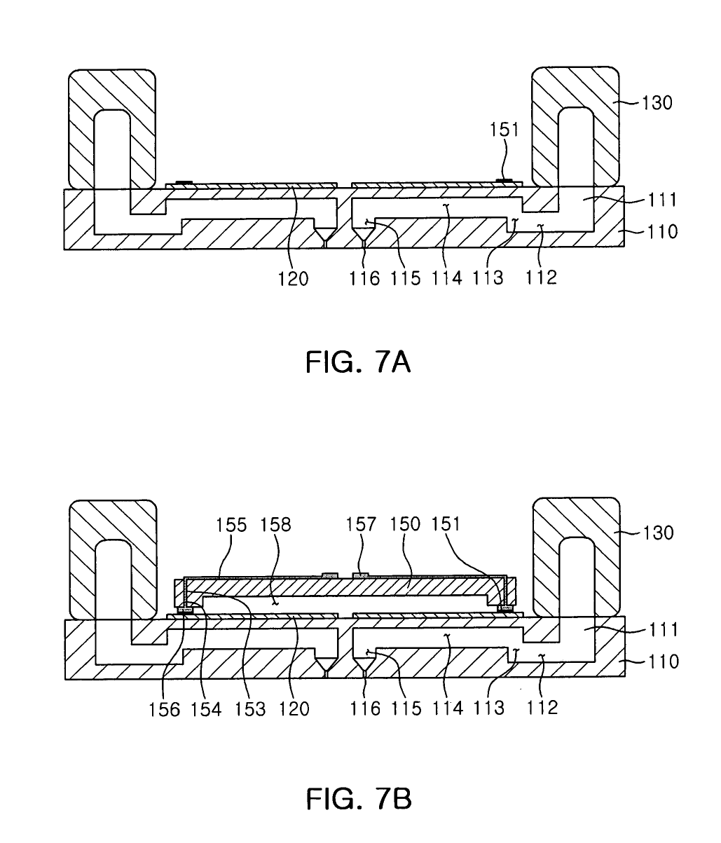

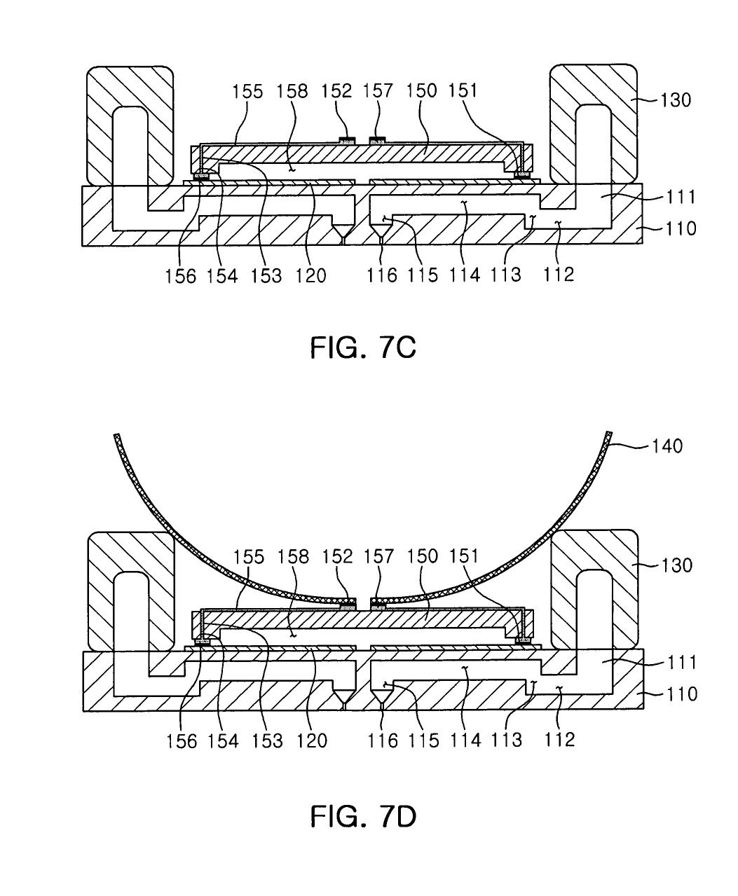

FIGS. 5A and 5B are process views showing a method for manufacturing the inkjet head plate of the inkjet head assembly according to an exemplary embodiment of the present invention, FIGS. 6A to 6C are process views showing a method for manufacturing the intermediate substrate of the inkjet head assembly according to an exemplary embodiment of the present invention, and FIGS. 7A to 7D are process views showing a method for assembling the inkjet head assembly according to an exemplary embodiment of the present invention.

As shown in FIG. 5A, the ink flow passage is first formed in the inkjet head plate 110. As the components of the ink flow passage, there may be the ink inlet 111 into which ink is introduced, the manifold 112 transporting the ink introduced into the ink inlet 111 to the ink flow passage of individual head cells, the plurality of pressure chambers 114 provided on the lower portion of a position in which the piezoelectric actuator 120 is mounted, and the plurality of nozzles 116 discharging the ink. The plurality of restrictors 113 may be formed between the manifold 112 and the pressure chambers 114 in order to restrain the ink in the pressure chambers 114 from flowing backward to the manifold 112 when the ink is discharged, and the plurality of dampers 115 may be formed between the pressure chambers 114 and the nozzles 116.

These components of the ink flow passage may be formed by performing an etching process on the inkjet head plate 110 composed of a single crystal silicon substrate or a SOI substrate. More specifically, the dry etching method such as the reactive ion etching (RIE) method using the ICP or the wet etching method using the TMAH or the KOH may be used.

As shown in FIG. 5B, the piezoelectric actuator 120 may be formed on the upper portion of the inkjet head plate 110 in which the ink flow passage is formed. The piezoelectric actuator 120 may be formed at the position corresponding to the pressure chambers 114 and may include the lower electrode serving as the common electrode, the piezoelectric film deformed according to the application of the voltage, and the upper electrode serving as the driving electrode.

Next, as shown in FIG. 6A, a substrate forming the intermediate substrate 150 is prepared. As the intermediate substrate 150, the epoxy resin based substrate, for example, the FR-4 substrate may be used.

As shown in FIG. 6B, a hole forming the via 153 and a groove forming the cavity 158 are formed in the intermediate substrate 150. The hole and the groove may be formed by the etching process. More specifically, the dry etching method such as the reactive ion etching (RIE) method using the ICP or the wet etching method using the TMAH or the KOH may be used.

As shown in FIG. 6C, the via conductor 154 is formed by filling the via 153 with the conductive material, and the wiring pattern 155 is formed on the upper surface of the intermediate substrate 150. The via conductor 154 may be formed by plating a metal in the via 153 through the electroplating method. As the metal, any one material selected from a group consisting of Pt, Au, Ag, Ni, Ti, Cu, and the like may be used. In addition, the wiring pattern 155 may be formed by printing or sputtering the metal material.

The first terminal electrode 156 may be formed on the lower end of the via conductor 154 in order to securely bond the intermediate substrate to the piezoelectric actuator 120, and the second terminal electrode 157 may be formed on the end of a FPCB side of the wiring pattern 155 in order to secure bond the intermediate substrate to the FPCB 140.

In addition, in order to protect the wiring pattern 155, the polymer film (not shown) may be applied to the upper surface of the intermediate substrate 150, with the exception of the portions in which the second terminal electrodes 157 are formed.

Meanwhile, although the exemplary embodiment of the present invention has described a case in which the via conductor 154 is connected to the first bonding portion 151 and the wiring pattern 155 is connected to the second bonding portion 152, the present invention is not limited thereto. The wiring pattern may be formed on the lower surface of the intermediate substrate 150 to be connected to the first bonding portion 151, and the via conductor may be formed to be connected to the second bonding portion 152. In addition, the present invention may be variously modified according to requirements and design specifications.

Next, a method for assembling the inkjet head assembly 100 according to an exemplary embodiment of the present invention will be described with reference to FIGS. 7A to 7D. As shown in FIG. 7A, the first bonding portion 151 is formed on the upper surface of the piezoelectric actuator 120. The first bonding portion 151 may be formed at the outer side of the piezoelectric actuator 120 in the width direction of the inkjet head plate 110, and may be formed on the first terminal electrode 156.

As shown in FIG. 7B, the intermediate substrate 150 is coupled to the inkjet head plate 110 by aligning the position of the first bonding portion 151 with the position at which the via conductor 154 of the intermediate substrate 150 is formed. At this time, the coupling through the first bonding portion 151 may be performed by conducting pre-bonding through thermal pressing and then conducting real-bonding using an ultrasonic wave.

As shown in FIG. 7C, the second bonding portion 152 for the boding to the FPCB 140 is formed on one end of the wiring pattern 155 of the intermediate substrate 150. That is, the first bonding portion 152 may be formed in the vicinity of the center in the width direction of the inkjet head plate 110, and may be formed on the second terminal electrode 157 of the wiring pattern 155.

As shown in FIG. 7D, the FPCB is disposed on the intermediate substrate 150 in such a manner as to be aligned with the intermediate substrate 150, and is bonded thereto through the second bonding portion 152. At this time, the bonding may be performed by conducting pre-bonding through the thermal pressing and then conducting real-bonding using the thermal pressing.

As set forth above, according to the exemplary embodiments of the present invention, there are provided the inkjet head assembly and a method for manufacturing the same in which the entire width of the inkjet head is reduced to increase the number of the inkjet heads capable of being manufactured on a single wafer, thereby allowing for an improvement in productivity such as an increase in processing yield, a decrease in a manufacturing costs, and the like.

Furthermore, in the inkjet head assembly according to the exemplary embodiments of the present invention, the physical stress applied to the FPCB when the FPCB is connected to the inkjet head is reduced, thereby allowing for improving the bonding characteristics of the FPCB.

Although the exemplary embodiments of the present invention have been described in detail, they are only examples. It will be appreciated by those skilled in the art that various modifications and equivalent other embodiments are possible from the present invention. For example, the method for forming the via conductor and the wiring pattern in the intermediate substrate in the inkjet head assembly according to the exemplary embodiment of the present invention is only an example. Various methods may be used and the order of each process of the method for manufacturing the inkjet head assembly may also be different from the order as described above. Accordingly, the actual technical protection scope of the present invention must be determined by the spirit of the appended claims.

What is claimed is:

1. An inkjet head assembly, comprising:
an inkjet head plate having an ink flow passage formed therein and having an actuator formed thereon, the actuator providing driving force for discharging ink therefrom;
a flexible printed circuit board (FPCB) applying voltage to the actuator; and
an intermediate substrate provided so as to electrically connect the actuator to the flexible printed circuit board and having a second bonding portion bonded to the flexible printed circuit board formed inwardly of a first bonding portion, bonded to the actuator, in a width direction of the inkjet head plate.

2. The inkjet head assembly of claim 1, wherein a conductor pattern connecting the first bonding portion to the second bonding portion is formed in the intermediate substrate.

3. The inkjet head assembly of claim 2, wherein each of a first terminal electrode and a second terminal electrode are formed at positions corresponding to the first and second bonding portions of the conductor pattern.

4. The inkjet head assembly of claim 1, wherein the intermediate substrate includes:
a wiring pattern formed on one surface of the intermediate substrate; and
a via conductor formed to penetrate through the intermediate substrate from one of the first bonding portion and the second bonding portion and connected to the wiring pattern.

5. The inkjet head assembly of claim 1, wherein a cavity is formed on a lower portion of the intermediate substrate so as to secure a vibration space of the actuator.

6. The inkjet head assembly of claim 1, wherein the first and second bonding portions are made of an anisotropic conductive film (ACF).

7. The inkjet head assembly of claim 1, wherein the intermediate substrate is a FR-4 (glass epoxy) substrate.

8. A method for manufacturing an inkjet head assembly, comprising:
preparing an inkjet head plate having an ink flow passage formed therein and having an actuator formed thereon, the actuator providing driving force for discharging ink;
preparing a flexible printed circuit board (FPCB) applying voltage to the actuator;
forming a conductor pattern in an intermediate substrate so as to electrically connect the actuator to the flexible printed circuit board;
forming a first bonding portion on an upper portion of the actuator and bonding the first bonding portion to a lower portion of the intermediate substrate;
forming a second bonding portion at an inner side in a width direction of the inkjet head plate than the first bonding portion on an upper portion of the intermediate substrate; and
bonding the flexible printed circuit board to the second bonding portion.

9. The method of claim 8, wherein the forming of the conductor pattern in the intermediate substrate includes:
forming a via to penetrate through the intermediate substrate at a position corresponding to one of the first bonding portion and the second bonding portion;
forming a via conductor by filling the via with a conductive material; and
forming a wiring pattern on one surface of the intermediate substrate, the wiring pattern connecting one end of the via conductor to the other of the first bonding portion and the second bonding portion.

10. The method of claim 8, further comprising forming a cavity on a lower portion of the intermediate substrate so as to secure a vibration space of the actuator.

11. The method of claim 10, wherein the forming of the cavity is performed by an etching method.

12. The method of claim 8, wherein the first and second bonding portions are made of an anisotropic conductive film (ACF).

13. The method of claim 8, wherein the intermediate substrate is a FR-4 (glass epoxy) substrate.

14. The method of claim 8, wherein the forming of the conductor pattern in the intermediate substrate includes forming each of a first terminal electrode and a second terminal electrode at positions corresponding to the first and second bonding portions of the conductor pattern.
